(19) United States
(12) Patent Application Publication
(10) Pub. No.: US 2007/0077715 A1
(43) Pub. Date: Apr. 5, 2007

(54) Semiconductor device and method of fabricating the same

(75) Inventors: Tae-Woong Kang, Suwon-si (KR); Byeong-Ryeol Lee, Seoul (KR); Sung-Man Hwang, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/541,569

(22) Filed: Oct. 3, 2006

(30) Foreign Application Priority Data
Oct. 4, 2005 (KR) 10-2005-0093002

(51) Int. Cl. H01L 21/336

(52) U.S. Cl. 438/299

(57) ABSTRACT

Example embodiments relate to a semiconductor device and a method of fabricating the same. A dummy pattern may be formed on a semiconductor substrate. Source and drain regions may be formed on the semiconductor substrate at sides of the dummy pattern. A first metal silicide layer may be formed on the source and drain regions. A recess region may be formed in the semiconductor substrate under the dummy pattern. A gate insulating layer and a gate electrode may be formed in the recess region.

### PRIORITY STATEMENT

This application claims the benefit of priority under 35 U.S.C. §119 from Korean Patent Application No. 10-2005-0093002, filed on Oct. 4, 2005, in the Korean Intellectual Property Office, the disclosure of which is incorporated herein by reference in its entirety.

### BACKGROUND OF THE INVENTION

1. Field of the Invention

Example embodiments relate to a semiconductor device and a method of fabrication the same. Other example embodiments relate to a semiconductor device having a recessed channel array transistor and a method of fabricating the same.

2. Description of the Related Art

As semiconductor devices become more highly integrated, the channel length of a transistor becomes shorter. The shorter channel length may cause various problems (e.g., punch through, leakage current, etc.). An increase in leakage current may undesirably decrease the data retention time of a memory cell. In a highly-integrated transistor, it may be difficult to form a silicide layer in the source and drain regions due to a leakage current caused by a small junction depth. As such, the contact resistance may increase.

The use of a recessed channel region in order to make formation of the silicide layer easier has been acknowledged. FIG. 1A is a diagram illustrating a cross-sectional view of a conventional recessed channel array transistor (RCAT), and FIG. 1B is a scanning electron microscope (SEM) image of a section of a recessed channel array transistor formed according to a conventional method.

Referring to FIG. 1A, a method of forming a conventional recessed channel array transistor will now be described. Shallow trench isolation (STI) layers 3 may be formed in a semiconductor substrate 1, and a recess region 5 may be formed in the semiconductor substrate 1. A gate insulating layer 6 and a polysilicon layer (not shown) may be formed on the semiconductor substrate 1 to fill the recess region 5. A void (V) may be formed in a lower portion of the recess region 5. The polysilicon layer may be patterned to form a gate electrode 7, and spacers 8 may be formed at sides of the gate electrode 7. An ion implantation process may be performed to form source and drain regions 9 beside the spacers 8. A heat treatment process may be performed to activate the impurities implanted in the ion implantation process.

The heat treatment process may be performed at a high temperature of about 1000° C. The high temperature may cause the polysilicon layer to flow. The void (V) of the polysilicon layer may migrate (or be moved) from the lower portion of the recess region 5 toward the gate insulating layer 6. As illustrated in FIG. 1B, the void (V) may be located (or formed) between the gate electrode 7 and the gate insulating layer 6 in the recess region 5. When the semiconductor device operates, the void may cause channel formation to be difficult or may cause a threshold voltage to increase, which may degrade the reliability of the semiconductor device. As illustrated in FIG. 1B, the heat treatment process performed at the high temperature may cause severe damage to the shallow trench isolation layers 3.

According to conventional methods, a desired region of a semiconductor substrate 1 may be etched to form a recess region 5. A gate conductive layer (not shown) may be deposited to fill (or formed in) the recess region 5. A photolithography process may be performed in order to form a gate electrode 7. When a highly-integrated semiconductor device is fabricated, misalignment with respect to the recess region 5 may occur during the photolithography process, which may have an undesirable effect upon characteristics of the transistor.

### SUMMARY OF THE INVENTION

Example embodiments relate to a semiconductor device and a method of fabricating the same. Other example embodiments relate to a semiconductor device having a recessed channel array transistor and a method of fabricating the same.

Example embodiments also relate a semiconductor device and a method of fabricating the same capable of improving reliability and achieving high integration.

According to example embodiments, a method of fabricating a semiconductor device may include forming a dummy pattern on a semiconductor substrate. Source and drain regions may be formed at sides of the dummy pattern on the semiconductor substrate. A first metal silicide layer may be formed on the source and drain regions. A recess region may be formed in the semiconductor substrate under the dummy pattern. A gate insulating layer and a gate electrode may be formed in the recess region.

In example embodiments, forming the dummy pattern may include depositing (or forming) a material layer having an etch selectivity with respect to a silicon oxide layer on the semiconductor substrate and patterning the material layer. According to example embodiments, a component ‘a’ having an etch selectivity with respect to a component ‘b’ means that the component ‘a’ can be etched while etching of the component ‘b’ is reduced (or non-existent).

In other example embodiments, forming the first metal silicide layer may include forming first spacers on sidewalls of the dummy pattern, depositing (or forming) a first metal layer on an entire surface of the semiconductor substrate having the dummy pattern and the first spacers and performing a heat treatment to silicidate the first metal layer. The method may include forming an etch stop (or stopper) layer covering the semiconductor substrate having the first metal silicide layer, forming an interlayer insulating layer on the etch stop (or stopper) layer and planarizing the interlayer insulating layer to expose the etch stop layer, selectively etching the etch stop layer to expose an upper surface of the dummy pattern and removing the dummy pattern to expose a surface of the semiconductor substrate.

In further example embodiments, forming the first metal silicide layer may include depositing (or forming) a first metal layer on an entire surface of the semiconductor substrate having the dummy pattern and performing a heat treatment to silicidate the first metal layer. The method may include forming an interlayer insulating layer on the semiconductor substrate such that the interlayer insulating layer covers the dummy pattern and has an etch selectivity with respect to the dummy pattern. The interlayer insulating layer may be planarized to expose the dummy pattern. The dummy pattern may be removed, forming first spacers facing each other on sidewalls of the interlayer insulating layer and exposing the semiconductor substrate between the first spacers.

In yet other example embodiments, the recess region may be formed by etching the exposed semiconductor substrate using the first spacers and the interlayer insulating layer as an etching mask. The method may include forming second spacers on sidewalls of the recess region and isotropically etching the semiconductor substrate exposed by a lower portion of the recess region. A bottom surface of the recess region may be lower than a bottom surface of the first metal silicide layer.

In further example embodiments, forming the gate electrode may include forming a gate conductive layer filling the recess region and planarizing the gate conductive layer to expose the interlayer insulating layer. A second metal layer may be deposited (or formed) on an entire surface of the semiconductor substrate having the exposed interlayer insulating layer. A heat treatment may be performed thereon in order to form a second metal silicide layer on the gate conductive layer.

In further example embodiments, the gate insulating layer may be formed at a temperature of about 850° C. or lower.

In yet further example embodiments, a method of fabricating a semiconductor device is provided. The method may include preparing a semiconductor substrate including a first region and a second region, forming a dummy pattern for a first gate electrode in the first region and forming a second gate insulating layer and a second gate electrode in the second region. Source and drain regions may be formed on the semiconductor substrate at sides of the dummy pattern. First spacers may be formed at sides of the dummy pattern and contacting sides of the second gate electrode. A first metal silicide layer may be formed on a top surface of the second gate electrode and on the source and drain regions. A recess region may be formed in the semiconductor substrate under the dummy pattern. A first gate insulating layer and a gate electrode may be formed in the recess region.

In yet other example embodiments, the dummy pattern may be formed by depositing (or forming) a material layer having an etch selectivity with respect to a silicon oxide layer and patterning the deposited material layer.

In further example embodiments, the method may include forming an etch stop (or stopper) layer covering the semiconductor substrate having the first metal silicide layer, forming an interlayer insulating layer on the etch stop layer, planarizing the interlayer insulating layer to expose the etch stop layer, selectivity etching the etch stop layer exposed in the first region while the second region is covered with a photoresist to expose an upper surface of the dummy pattern and removing the dummy pattern to expose a surface of the semiconductor substrate in the first region.

In other example embodiments, the recess region may be formed by etching the exposed semiconductor substrate in the first region using the first spacers and the interlayer insulating layer as an etching mask. The method may include forming second spacers on sidewalls of the recess region and isotropically etching the semiconductor substrate exposed by a lower portion of the recess region.

In yet other example embodiments, a bottom surface of the recess region may be lower than a bottom surface of the first metal silicide layer.

According to example embodiments, forming the first gate electrode may include forming a gate conductive layer filling the recess region and planarizing the gate conductive layer to expose the interlayer insulating layer. A second metal layer may be deposited (or formed) on an entire surface of the semiconductor substrate having the exposed interlayer insulating layer. A heat treatment may be performed on the second metal layer to form a second metal silicide layer on the gate conductive layer. In yet other example embodiments, the second metal silicide layer may be a nickel silicide layer.

In further example embodiments, a semiconductor device is provided. The semiconductor device may include a first gate insulating layer and a first gate electrode formed in a recess region of a semiconductor substrate. A first source region and a first drain region may be formed in the semiconductor substrate at sides of the first gate electrode. A first metal silicide layer may be formed on the first source region and the first drain region. The first gate electrode may include a second metal silicide layer thereon. The first metal silicide layer and the second metal silicide layer may be formed of different metals.

In other example embodiments, the semiconductor device may also include a second gate insulating layer and a second gate electrode formed in another region of the semiconductor substrate; a second source region and a second drain region formed in the semiconductor substrate at sides of the second gate electrode and a first metal silicide layer formed on the second source region and the second drain region. The second gate electrode may include the first metal silicide layer formed thereon.

In yet other example embodiments, the first metal silicide layer may maintain a stable state at a temperature of about 850° C. or lower. In further example embodiments, the first metal silicide layer may be a cobalt silicide layer or a titanium silicide layer. The second metal silicide layer may be a nickel silicide layer.

In other example embodiments, the recess region may include a first recess region formed in the semiconductor substrate and a second recess region connected with the first recess region under the first recess region. The second recess region may have a circular profile.

In yet other example embodiments, the semiconductor device may include spacers formed at sides of the first and second gate electrodes. The first metal silicide layer may be self-aligned with the spacers.

### BRIEF DESCRIPTION OF THE DRAWINGS

The accompanying drawings, which are included to provide a further understanding of the embodiments and are incorporated in and constitute a part of this application. FIGS. 1-34 illustrate example embodiments and together with the description serve to explain the principle of the invention.

FIG. 1A is a diagram illustrating a cross-sectional view of a conventional recessed channel array transistor (RCAT);

FIG. 1B is a scanning electron microscope (SEM) image of a section of a recessed channel array transistor formed according to a conventional method;

FIGS. 2 to 28 are diagrams illustrating cross-sectional views of a method of fabricating a semiconductor device according to example embodiments; and

FIGS. 29 to 34 are diagrams illustrating cross-sectional views of a first region (A) of a method of fabricating a semiconductor device according to example embodiments

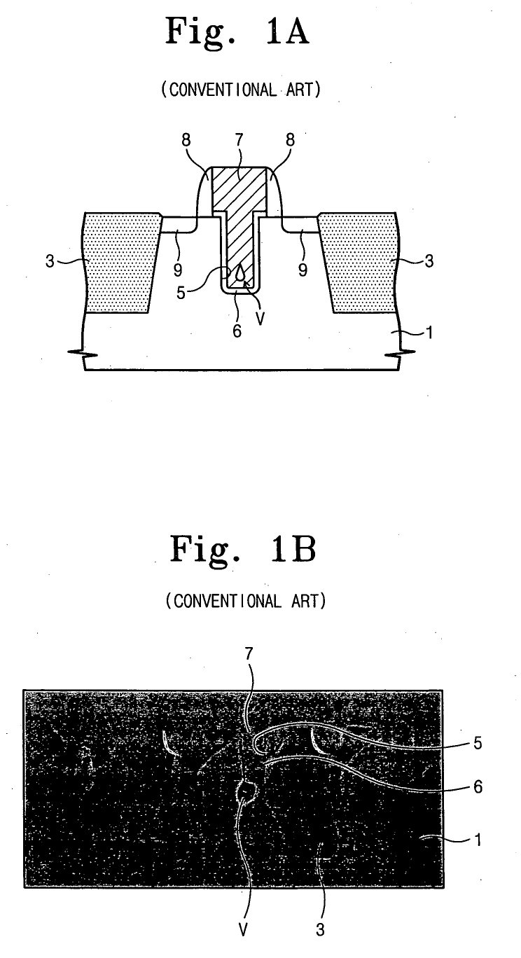

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

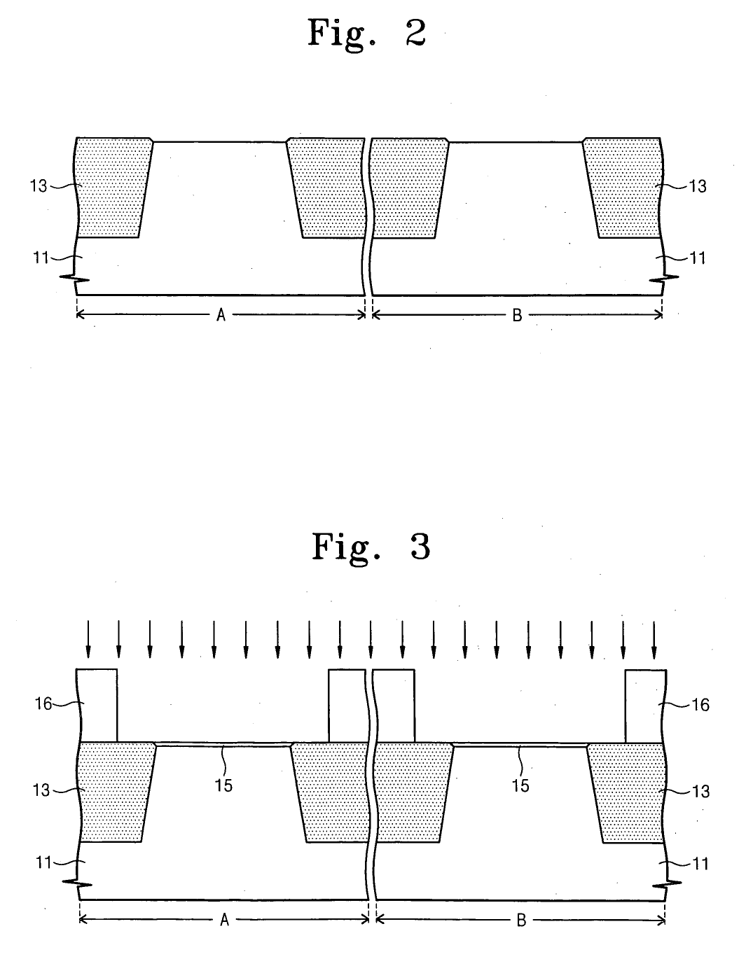

FIGS. 2 to 28 are diagrams illustrating cross-sectional views of a method of fabricating a semiconductor device according to example embodiments.

Referring to FIG. 2, device isolation layers 13 may be formed in a semiconductor substrate 11 having a first region (A) and a second region (B) in order to define active regions. The device isolation layers 13 may be formed by any shallow trench isolation (STI) method well-known in the art. The first region (A) and the second region (B) may be regions where transistors having different characteristics are formed (e.g., a memory cell region and a peripheral circuit region, respectively).

Referring to FIG. 3, a buffer oxide layer 15 may be formed on a surface of the semiconductor substrate 11. Impurity ions may be implanted to control a threshold voltage of a transistor. The buffer oxide layer 15 may be a thermal oxide layer or a chemical vapor deposition (CVD) oxide layer. The buffer oxide layer 15 may have a thickness of 50-200 Å. If desirable, other impurity ions may be implanted separately in the first region (A) and the second region (B) or a desired portion defined within each region. The regions or different portions within each region may have different threshold voltages.

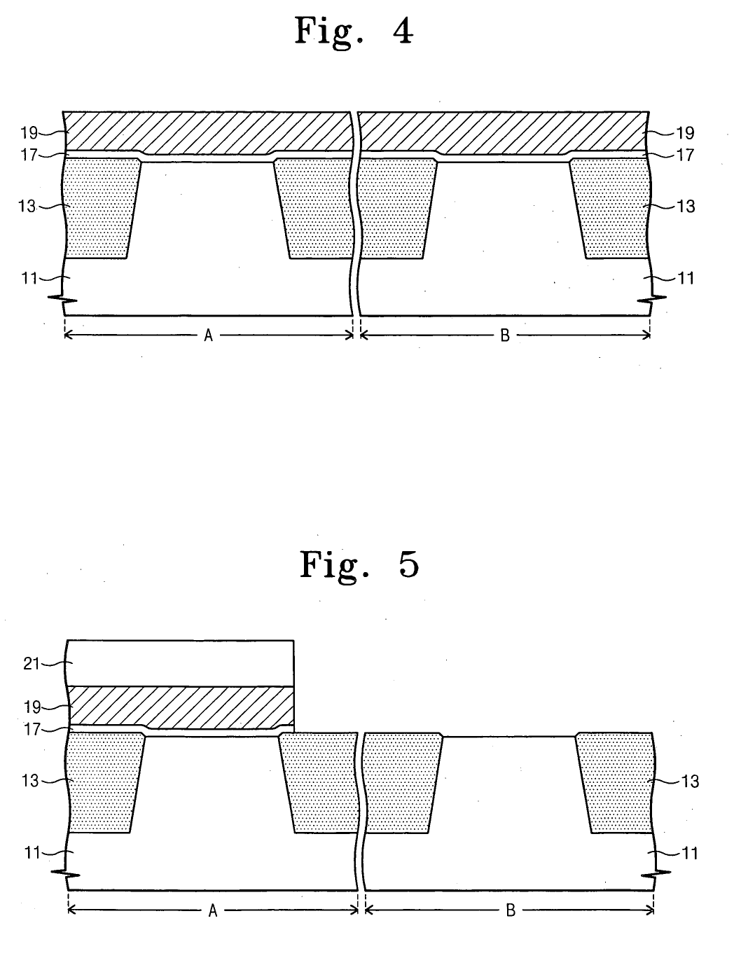

Referring to FIG. 4, a dummy gate layer 19 may be formed on the semiconductor substrate 11. The dummy gate layer 19 may be formed on a pad oxide layer 17. The pad oxide layer 17 may include a silicon oxide layer. The dummy gate layer 19 may be formed of a material having an etch selectivity with respect to the silicon oxide layer. The etch selectivity ratio of the dummy gate layer to the silicon oxide layer may be 5:1 or greater during a dry-etching or wet etching process. The silicon oxide layer of the pad oxide layer 17 may be formed after the buffer oxide layer 15 is removed by a wet-etching method. The silicon oxide layer of the pad oxide layer 17 may be formed by a chemical vapor deposition (CVD) method such that the buffer oxide layer 15 remains. The dummy gate layer 19 may be an insulating layer including nitride. The dummy gate layer 19 may be formed by the CVD method. The insulating layer may include a silicon nitride layer (SiN) or a silicon oxide nitride layer (SiON). The pad oxide layer 17 and the dummy gate layer 19 may have thicknesses of 100-500 Å and 500-2000 Å, respectively.

Referring to FIG. 5, a photoresist layer (not shown) may be formed on the semiconductor substrate 11. A photoresist pattern 21 may be formed by an exposure process wherein the photoresist layer on the second region (B) is exposed. A dry-etching process may be performed using the photoresist pattern 21 as an etching mask in order to remove the dummy gate layer 19 of the second region (B). A portion of the pad oxide layer 17 in the second region (B) may remain during the dry etching process. The portion of the pad oxide layer 17 remaining in the second region (B) may be removed during a subsequent wet etching process in order to expose the semiconductor substrate. If the amount of the pad oxide layer 17 remaining on the second region (B) is too large, then the semiconductor substrate 11 may be partially damaged due to an increase in etching amount. The increase in etching amount may cause deterioration of the semiconductor device. Preferably, the thickness of the pad oxide layer 17 remaining after the dry etching may be maintained at (or controlled to) about 100 Å or less.

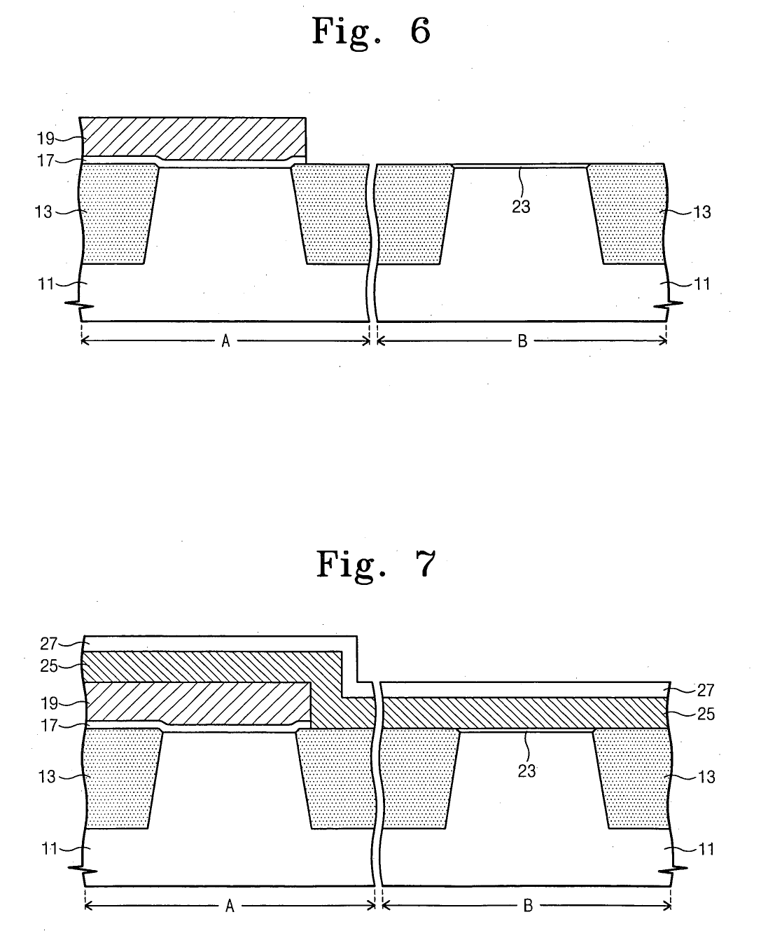

Referring to FIG. 6, the photoresist pattern 21 may be removed. A cleaning process may be performed. A gate oxide layer 23 may be formed on the semiconductor substrate 11 of the second region (B). The gate oxide layer 23 may be a thermal oxide layer grown (or formed) using a conventional method at a temperature of 900 to 1000° C.

Referring to FIG. 7, a gate conductive layer 25 and a first hard mask layer 27 may be formed on an entire surface of the semiconductor substrate 11. The gate conductive layer 25 may be a polysilicon layer doped with impurity ions. The first hard mask layer 27 may have an etch selectivity with respect to a polysilicon layer. The first hard mask layer 27 may include a silicon dioxide layer (SiO₂), silicon nitride layer (SiN) and/or silicon oxide nitride layer (SiON). The gate conductive layer 25 and the first hard mask 27 may have thicknesses of about 500-1500 Å and about 300-1000 Å, respectively.

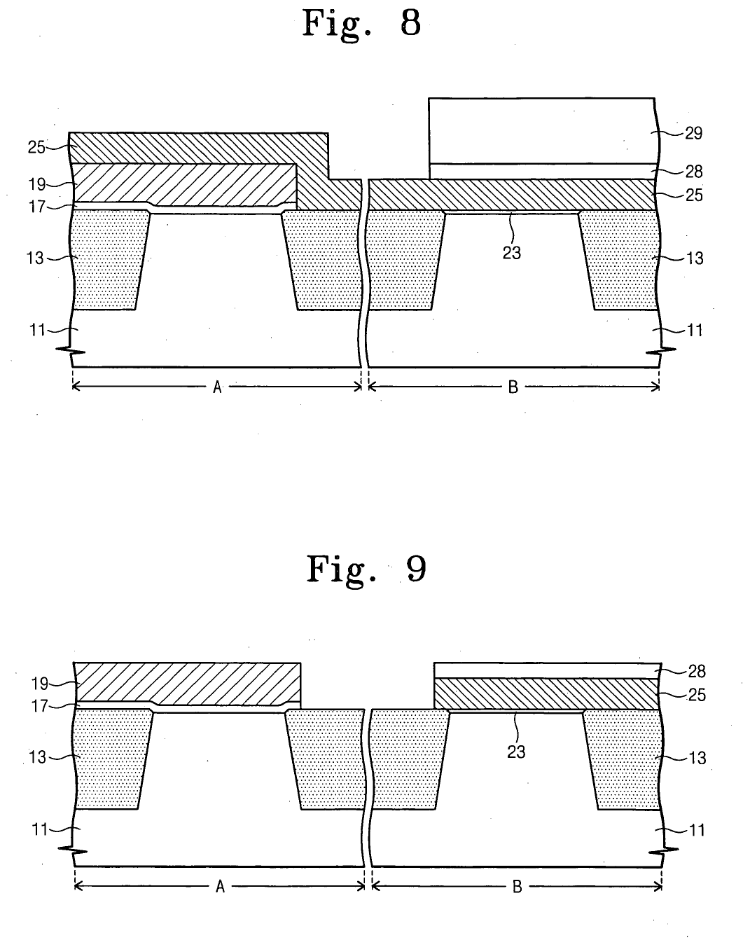

Referring to FIG. 8, a photoresist pattern 29, which exposes the first region (A), may be formed. The first hard mask layer 27 may be patterned using the photoresist pattern 29 as an etching mask in order to form a first hard mask pattern 28.

Referring to FIG. 9, the photoresist pattern 29 may be removed. The gate conductive layer 25 on the first region (A) may be removed by an etching process using the first hard mask pattern 28 as an etching mask. The etching process may be performed to selectively etch the gate conductive layer 25. The etching process may be controlled in order not to etch (or remove) an oxide material surface of the device isolation layer 13. The etching process may be performed such that an etch selectivity ratio of the gate conductive layer 25 to the oxide material surface is 10:1 or greater. The etching process may be controlled in order not to etch the dummy gate layer 19 of the first region (A).

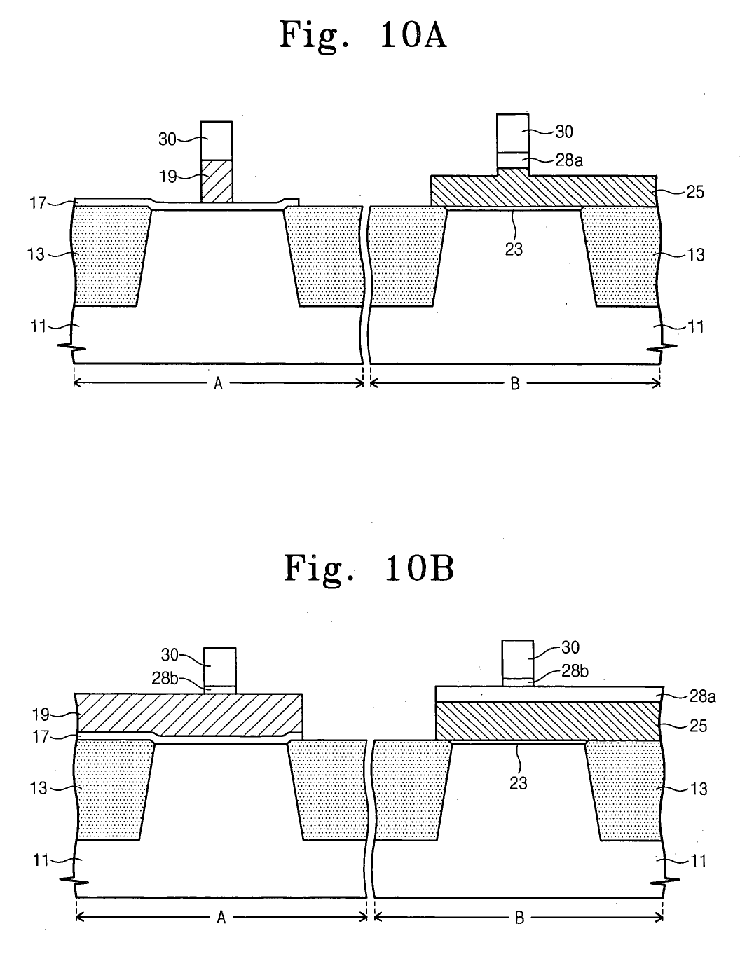

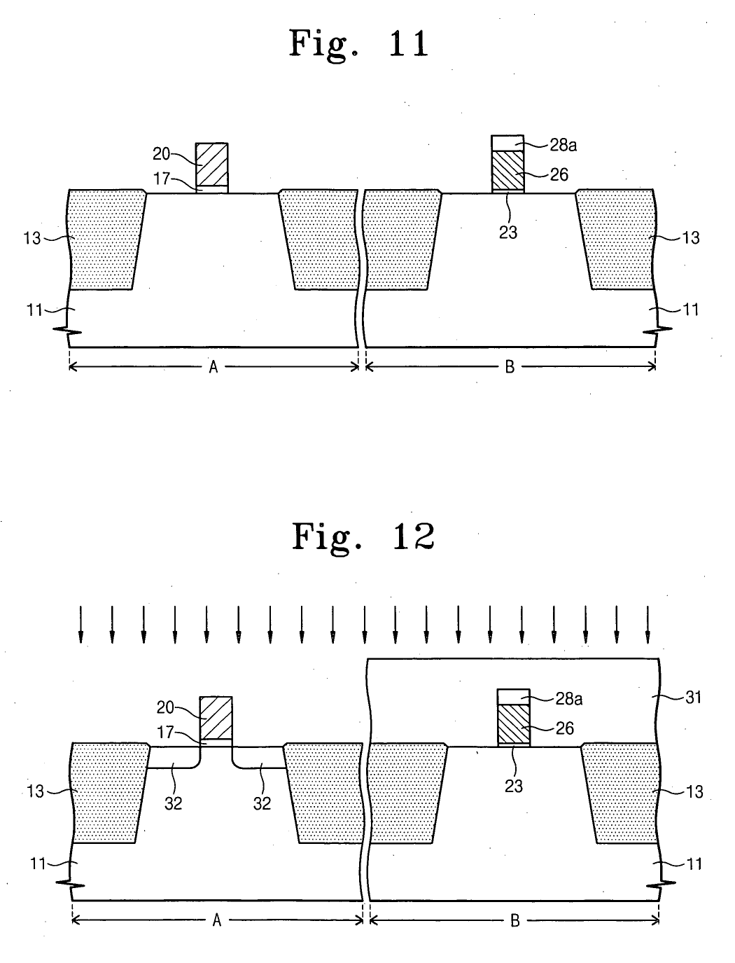

Referring to FIG. 10A and FIG. 11, a photoresist layer may be formed on the semiconductor substrate 11. A photoresist pattern 30 may be formed by performing a photolithography process, which is used to form a gate electrode, on the photoresist layer. The dummy gate layer 19 may be patterned by an etching process using the photoresist pattern 30 as an etching mask to form a dummy pattern 20 in the first region (A). The dummy pattern 20 may be used to form a first gate electrode (not shown) on the first region (A) (formation of the first gate electrode from the dummy pattern 20 will be described below). A first hard mask pattern 28a may be simultaneously formed in the second region (B). The etching process may be preferably performed selectively such that the gate conductive layer 25 of the second region (B) is not etched. As shown in FIG. 10A, slight over-etching may occur, forming a raised portion in the gate conductive layer 25.

Referring to FIG. 11, the photoresist pattern 30 may be removed. The exposed pad oxide layer 17 and gate conductive layer 25 may be dry-etched by an etching process using the dummy pattern 20 and the first hard mask pattern 28a as an etching mask, respectively. At first, the etching process may be performed under conditions where an etch selectivity ratio of the silicon oxide layer to the gate conductive layer 25 is almost 1:1. The etching process (and the etch selectivity ratio) may be controlled (or maintained) such that the pad oxide layer 17 becomes relatively thin having a thickness of about 100-200 Å. Then, the etching process may be performed such that the etch selectivity of the gate conductive layer 25 is higher than the exposed pad oxide layer 17, whereby the etching damage on the semiconductor substrate 11 of the first region (A) may be reduced. The dummy pattern 20 and a second gate electrode 26 are formed in the first region (A) and the second region (B), respectively.

Referring to FIG. 12, impurity ions may be implanted in the first region (A) using a photoresist pattern 31, which covers the second region (B) and exposes the first region (A), as an etching mask in order to form impurity regions 32. If the semiconductor device is a n-channel metal oxide semiconductor (NMOS) transistor, then the impurity region 32 may be formed by implanting phosphorous or arsenic with an energy of 10-30 keV and a dose of approximately 5×10¹⁴-1×10¹⁵ atoms/cm². If the semiconductor device is a p-channel metal oxide semiconductor (PMOS) transistor, then boron ions may be implanted with an energy of 10-30 keV and a dose of approximately 5×10¹⁴-1×10¹⁵ atoms/cm². The photoresist pattern 31 and the first hard mask pattern 28a may be removed.

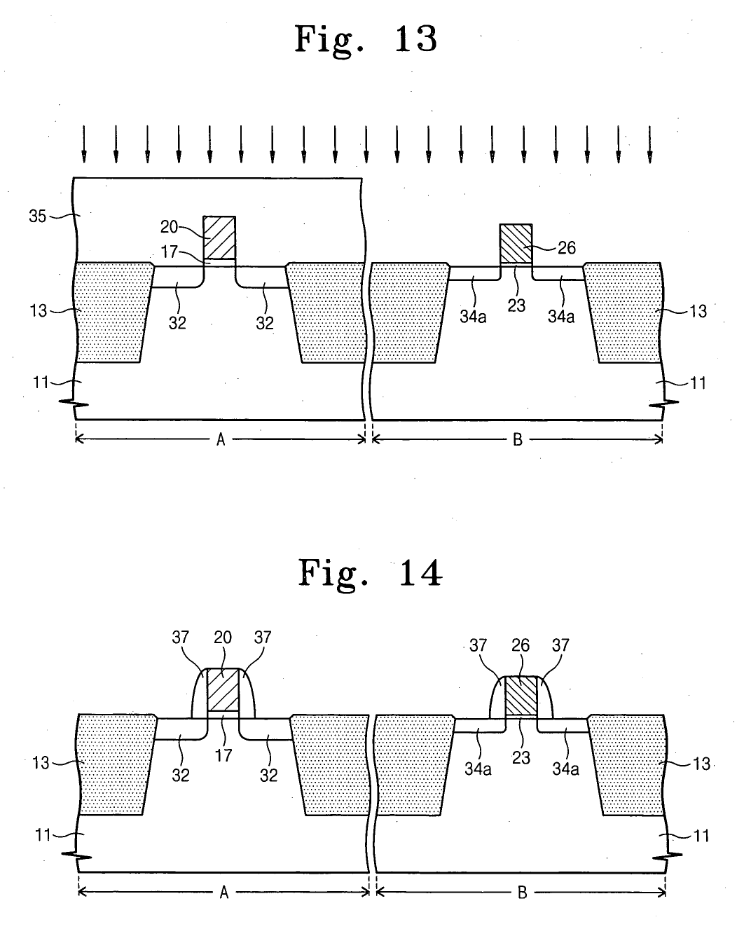

Referring to FIG. 13, low-concentration impurity ions may be implanted in the second region (B) using a photoresist pattern 35, which covers the first region (A) and exposes the second region (B), as an etching mask in order to form a low-concentration impurity region 34a. The second region (B) may have both NMOS and PMOS transistors. As such, a photoresist process and an ion implantation process may be performed separately for the NMOS and the PMOS transistors.

If the semiconductor device is a NMOS transistor, then the low-concentration impurity region 34a may be formed by implanting phosphorous or arsenic with an energy of 10-30 keV and a dose of approximately 5×10¹⁴-1×10¹⁵ atoms/cm². If the semiconductor device is a PMOS transistor, then boron ions may be implanted with an energy of 10-30 keV and a dose of approximately 5×10¹⁴-1×10¹⁵ atoms/cm². The photoresist pattern 35 may be removed.

Referring to FIG. 14, an insulating layer (not shown) may be deposited (or formed) on a surface of the semiconductor substrate. A dry etching process may be performed thereon to form first spacers 37 on sidewalls of the dummy pattern 20 and the second gate electrode 26. The insulating layer for forming the spacers 37 may have an etch selectivity with respect to the dummy pattern 20 and the first gate electrode 26. The insulating layer may be a silicon oxide layer formed by chemical vapor deposition (CVD) (in other words, a CVD silicon oxide layer).

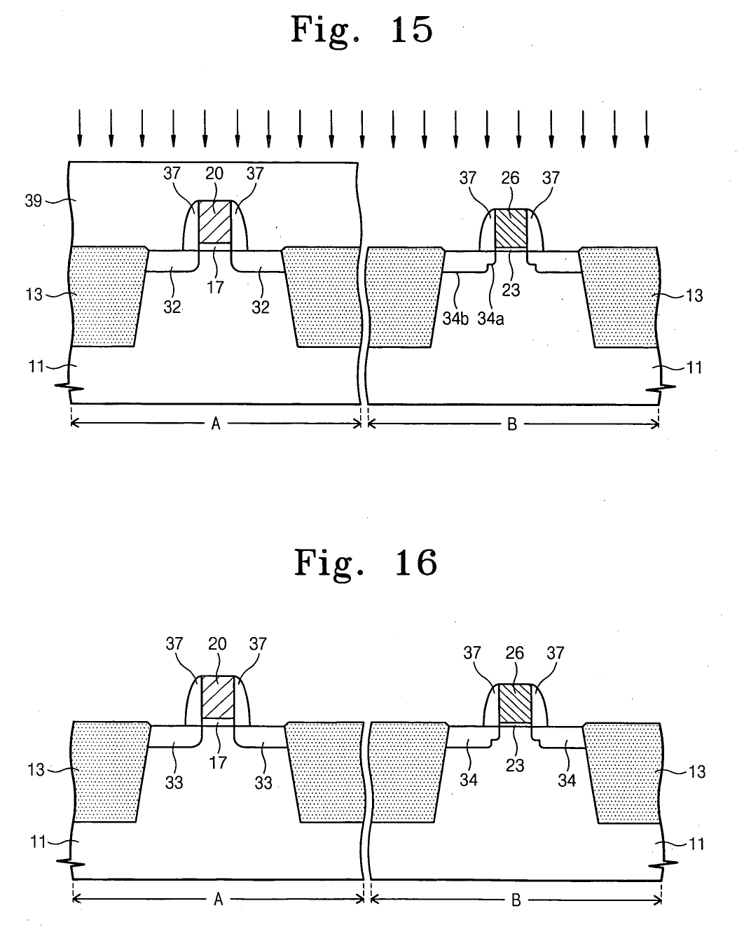

Referring to FIG. 15, high-concentration impurity ions may be implanted in the second region (B) using a photoresist pattern 39, which covers the first region (A) and exposes the second region (B), as an etching mask in order to form a high-concentration impurity region 34b. As such, an impurity region 34 having the low-concentration impurity region 34a and the high-concentration impurity region 34b is formed. Because the second region (B) may have an NMOS and PMOS transistors, a photoresist process and an ion implantation process may be performed separately for the NMOS and the PMOS transistor. The depth at which the high-concentration ions are implanted may be greater than the depth of a first metal silicide layer (not shown) (discussed below). The difference in depth between the high-concentration ions and the first metal silicide layer may prevent (or reduce) a leakage current generated when a metal silicide layer is formed deeper than the source and drain regions. High-concentration impurity ions may be formed in the first region (A) (if desired) in a similar manner as the high-concentration impurity ions formed in the second region (B).

If the semiconductor device is a NMOS transistor, then the high-concentration impurity region 34b may be formed by implanting phosphorous or arsenic with an energy of 30-50 keV and a dose of approximately 1×10¹⁵-5×10¹⁵ atoms/cm². If the semiconductor device is a PMOS transistor, then boron ions may be implanted with an energy of 30-50 keV and a dose of approximately 1×10¹⁵-5×10¹⁵ atoms/cm².

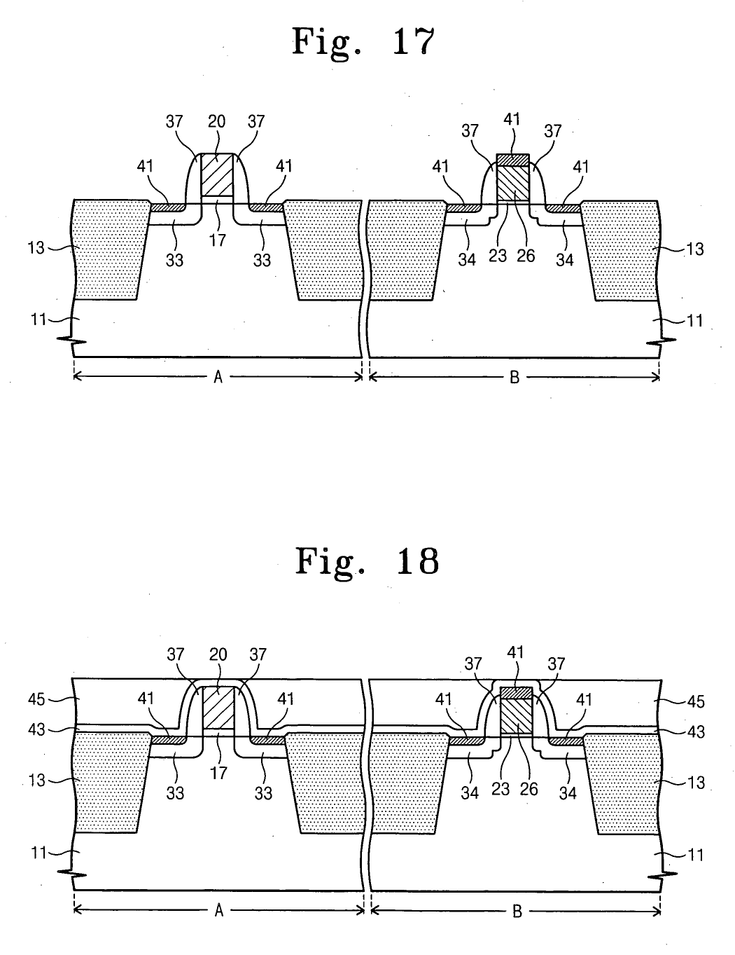

Referring to FIG. 16, the photoresist pattern 39 may be removed, and a heat treatment process may be performed to activate the impurity ions implanted in the semiconductor substrate, forming source and drain regions 33 and 34. The source and drain regions 33 may be formed at sides of the dummy pattern 20 in the first region (A). The source and drain regions 34 may be formed at sides of the second gate electrode 26 in the second region (B). The source and drain regions 34 of the second region (B) may have an lightly doped drain (LDD) structure. The heat treatment process may be performed at a high temperature (e.g., about 1000° C.).

Referring to FIG. 17, a first metal layer (not shown) may be deposited (or formed) and heat-treated in order to form a first metal silicide layer 41 on a upper surface of the second gate electrode 26. The first metal layer may be formed on the source and drain regions 33 and 34. The first metal layer may be formed of a metal including cobalt, titanium or any metal capable of maintaining stable properties thereof during a high temperature process. The high temperature processes include a thermal oxidation process performed at a temperature of 850° C. or lower in order to form a gate insulating layer in the first region (A). If the first metal layer is a cobalt layer, then a first heat-treatment may be performed on the cobalt layer in a temperature range of 450-540° C. Unreacted cobalt may be removed by a wet etching solution. A second heat treatment may be performed thereon in a temperature range of 700-850° C. in order that a cobalt silicide layer may be formed. If the first metal layer is a titanium layer, then a first heat treatment may be performed on the titanium layer at a temperature of about 650° C. Unreacted titanium may be removed by a wet-etching solution. A second heat treatment may be performed thereon at a temperature of about 800° C. in order that a titanium silicide layer may be formed.

As a result, the first metal silicide layer 41 may be a cobalt silicide layer or a titanium silicide layer. The first metal silicide layer 41 may be formed on the source and drain regions 33 and 34. The first metal silicide layer 41, which is formed on the source and drain regions 33 and 34, may be self-aligned with the first spacers 37.

Referring to FIG. 18, a first interlayer insulating layer 43 and a second interlayer insulating layer 45 may be sequentially deposited (or formed). The first interlayer insulating layer 43 may function as an etch stop (or stopper layer) during subsequent etching and chemical mechanical planarization (CMP) processes. The first interlayer insulating layer 43 may have an etch selectivity with respect to the second interlayer insulating layer 45. The first interlayer insulating layer 43 may be formed of a silicon nitride (SiN) layer or a silicon oxide nitride (SiON) layer. The first interlayer insulating layer may have a thickness of about 200-1000 Å. The second interlayer insulating layer 45 may have a thickness sufficient to cover understructures when planarized. The second interlayer insulating layer 45 may be formed of a silicon oxide layer (e.g., a high density plasma oxide layer, a borophospho silicate glass (BPSG) oxide layer, a plasma-enhanced tetraethyl orthosilicate oxide (PE-TEOS) layer or the like).

The second interlayer insulating layer 45 may be planarized when the first interlayer insulating layer 43 is exposed during etching. The etching and/or planarization may be performed using a chemical mechanical polishing (CMP) process wherein the second interlayer insulating layer 45 has an etch selectivity with respect to the first interlayer insulating layer 43.

Referring to FIG. 19, a photoresist pattern 48 may be formed on the second region (B). The first interlayer insulating layer 43 exposed in the first region (A) may be etched. Because the first interlayer insulating layer 43 has an etch selectivity with respect to the second interlayer insulating layer 45, the exposed portion of the first interlayer insulating layer 43 is selectively etched and removed, exposing the dummy pattern 20.

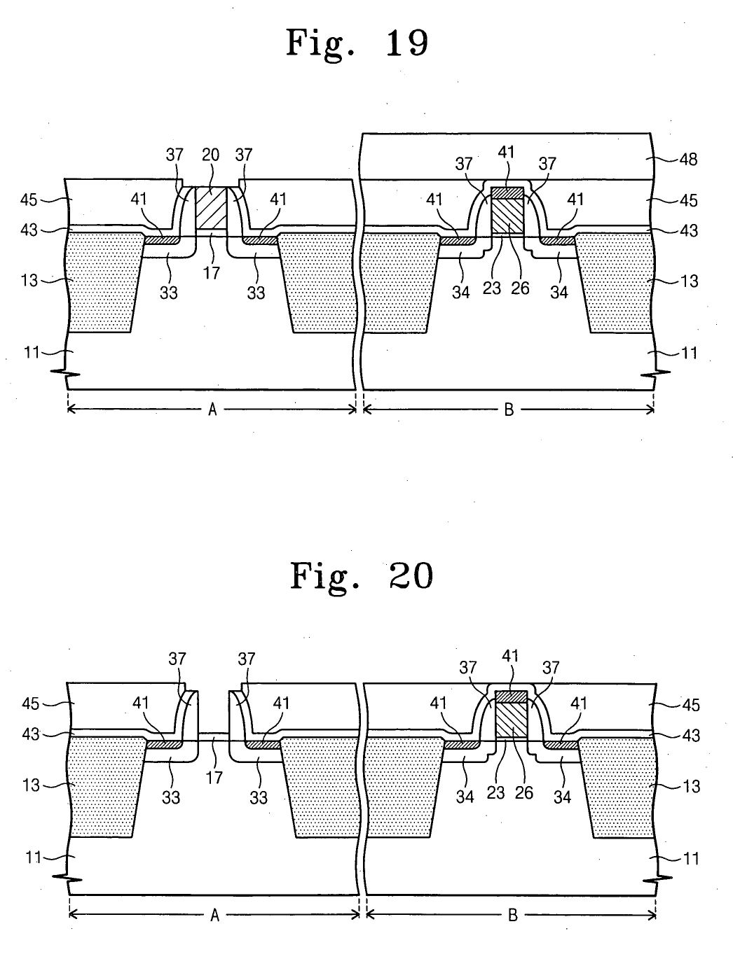

Referring to FIG. 20, the dummy pattern 20 may be selectively removed while the photoresist pattern 48 is formed on the second region (B). The dummy pattern 20 may be removed by wet etching. Because the dummy pattern 20 may be formed of a material having an etch selectivity with respect to a silicon oxide layer (as described above), the dummy pattern 20 may be selectively removed while the spacers 37 and the second insulating layer 45 remain. The photoresist pattern 48 may be removed.

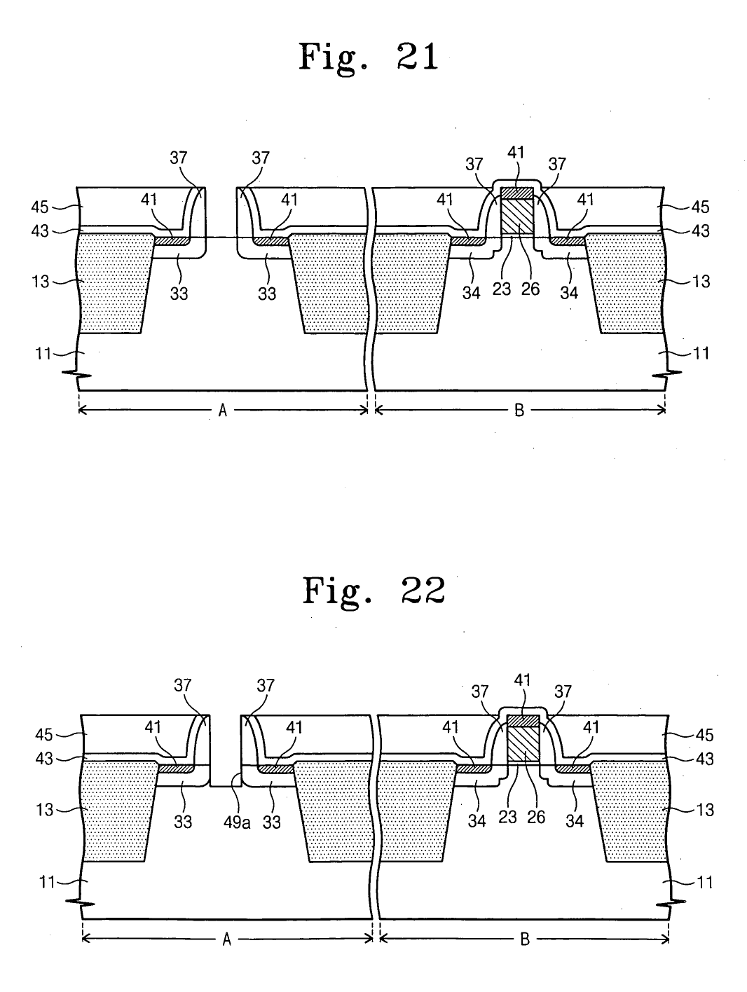

Referring to FIG. 21, an entire surface of the semiconductor substrate may be etched by performing a dry etching process in order to remove the pad oxide layer 17 under the dummy pattern 20 and expose the semiconductor substrate 11. The second interlayer insulating layer 45 may be partially removed. Removal of the second interlayer insulating layer 45 may be performed simultaneously with the dry etching process.

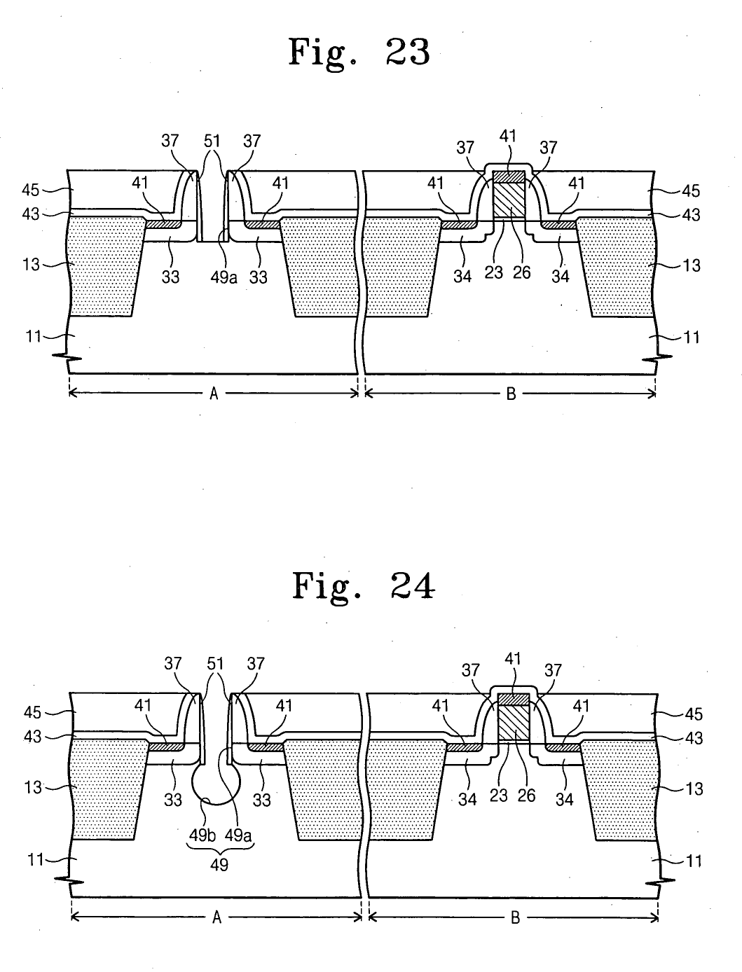

Referring to FIG. 22, the exposed semiconductor substrate 11 may be anisotropically etched using the first interlayer insulating layer 43, the second interlayer insulating layer 45 and the spacers 37 as an etching mask. Anisotropic etching may include dry etching. A first recess region 49a may be formed. The first recess region 49a may be formed at a depth of 400-1000 Å. The first recess region 49a may be formed deeper than a lower (or bottom) surface of the first metal silicide layer 41.

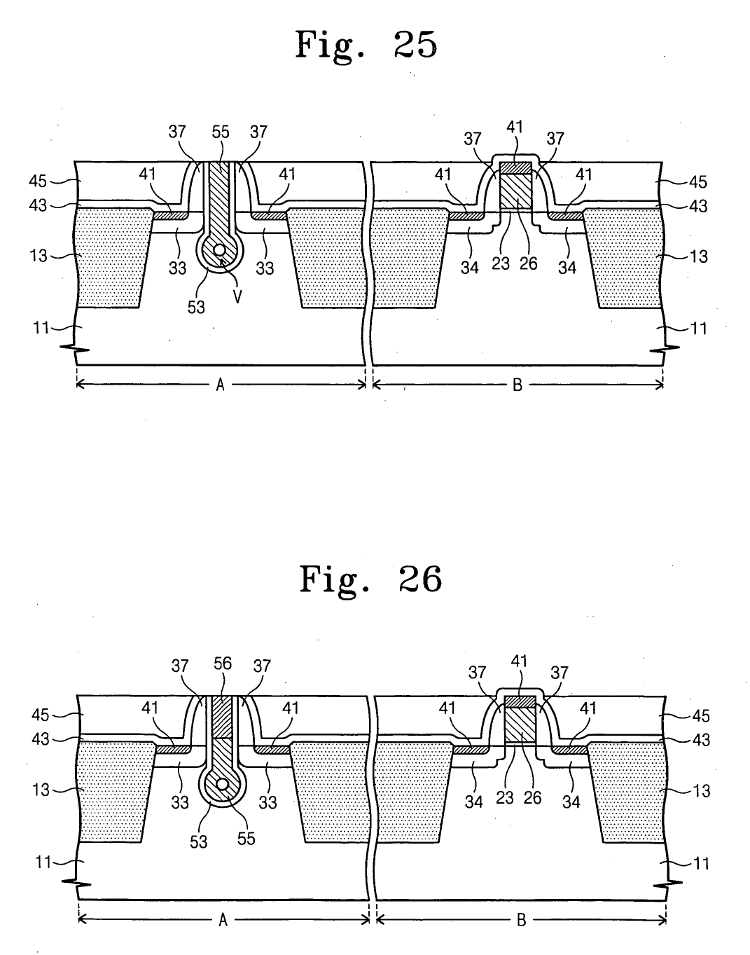

Referring to FIG. 23, an etching barrier layer (not shown) may be conformably formed on the semiconductor substrate 11 having a thickness of 50-300 Å. An anisotropic etching process may be performed on the etching barrier layer in order to form etching barrier spacers 51 covering sidewalls of the first recess region 49a and exposing a bottom surface of the first recess region 49a. The etching barrier layer may be formed of a material having different etch selectivity with respect to the semiconductor substrate 11 (e.g., a silicon nitride layer, a silicon oxide nitride layer, a silicon oxide layer or the like).

Referring to FIG. 24, an isotropic etching process may be performed on the semiconductor substrate 11 having the etching barrier spacers 51 in order that a second recess region 49b having a circular profile may be formed under the first recess region 49a. The etching process may be performed to a depth of 300-1000 Å. The isotropic etching process may include a wet etching process. The etching barrier spacers 51 may function to prevent (or reduce) etching of the sidewalls of the first recess region 49a during the isotropic etching process.

A recess region 49, which includes the first recess region 49a and a second recess region 49b, may be formed. The first recess region 49a may be formed in the semiconductor substrate 11. The second recess region 49b may be connected with the first recess region 49a under the first recess region 49a. The second recess region 49b may have a circular profile.

Referring to FIG. 25, the etching barrier spacers 51 may be removed to expose the recess region 49. A cleaning process may be performed on the exposed recess region 49. A gate insulating layer 53 may be conformably formed thereon. The gate insulating layer 53 may be a silicon oxide layer formed through a thermal oxidation process performed at a temperature of approximately 850° C. The gate insulating layer may be a high-k dielectric insulating layer (e.g., a hafnium oxide layer (HfO₂), an aluminum oxide layer (Al₂O₃), a zirconium oxide layer (ZrO₂), a tantalum oxide layer (Ta₂O₅), a titanium oxide layer (TiO₂), a lanthanum oxide layer (La₂O₃) or a hafnium silicon oxide layer (HfₓSi₁₋ₓO₂)) formed by an atomic layer deposition (ALD) process. The ALD process may be performed at a temperature sufficiently high to form a gate oxide layer and maintain properties thereof without any (or minimal) damage to the first metal silicide layer 43.

A gate conductive layer (not shown) may be formed on an entire surface of the semiconductor substrate 11 to fill the recess region 49. A void (V) may be formed in the recess region 49. The gate conductive layer may be formed of a polysilicon layer doped with impurities. The gate conductive layer may be formed of a metal layer formed by a CVD method. The gate conductive layer may be formed as a multi-layer including a polysilicon layer and the metal layer.

The gate conductive layer may be planarized by etching until the first interlayer Insulating layers 43 and the second interlayer insulating layer 45 of the second region (B) are exposed. The gate conductive layer may be etched by a chemical mechanical polishing (CMP) process having an etch selectivity with respect to the second interlayer insulating layer 45 and the first interlayer insulating layer 43. Residues of the gate conductive layer may remain on a portion of an upper surface of the second interlayer insulating layer 45 after the CMP process. In order to remove the residues, a dry-etching process may be additionally performed. A first gate electrode 55 filling the recess region 49 in the first region (A) is formed.

Referring to FIG. 26, if the gate conductive layer for the first gate electrode 55 is formed of a polysilicon layer, then a second metal layer (not shown) may be deposited (or formed) on an entire surface of the semiconductor substrate 11. The second metal layer may be heat-treated in order to form a second metal silicide layer 56 on the first gate electrode 55. The second metal layer may be selected from metal layers having lower silicidation temperatures than that of the first metal layer, in order to prevent (or reduce) deformation or damage to a transistor formed in the recess region due to the silicidation heat treatment process. The second metal layer may be a nickel layer.

If the second metal layer is a nickel layer, then a first heat treatment may be performed on the nickel layer at a temperature of about 300° C. Unreacted nickel may be removed using a wet etching solution. A second heat treatment may be performed thereon in a temperature range of 400-530° C. The second metal silicide layer may be a nickel silicide layer.

In the aforementioned manner, the first metal silicide layers 41 may be formed in the source and drain regions 33 and 34 and on the second gate electrode 26. The second metal silicide layer 56 may be formed on the first gate electrode 55, fabricating a semiconductor device according to the example embodiments.

Hereinafter, a semiconductor device fabricated using transistors formed according to example embodiments will be described using a dynamic random-access memory (DRAM) device as an example. However, the example embodiments are not limited to the DRAM device.

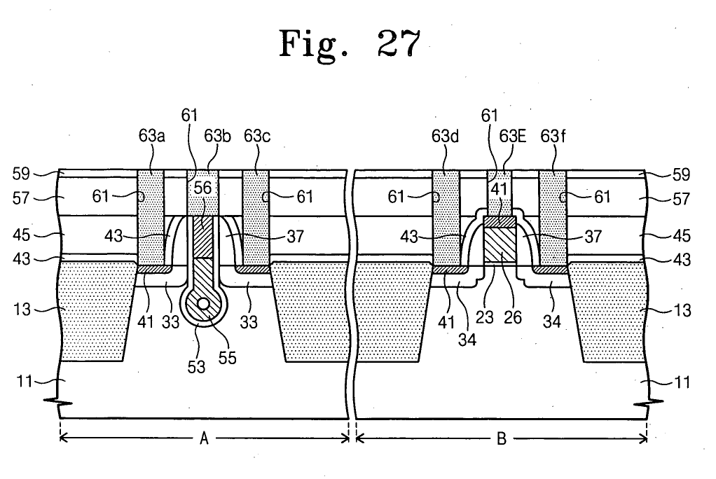

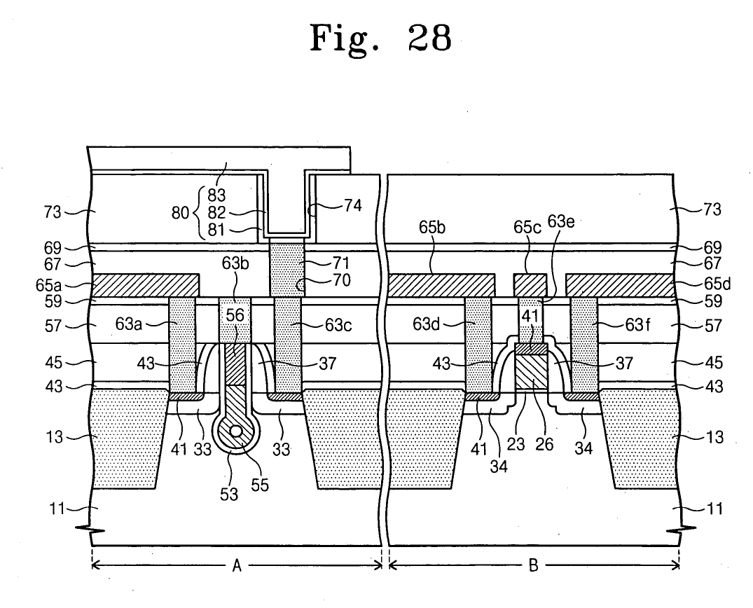

Referring to FIG. 27, a third interlayer insulating layer 57 and a second hard mask layer 59 may be deposited (or formed) by any deposition method well-known in the art. The third interlayer insulating layer 57 may be an insulating layer having a thickness sufficient to cover understructures when planarized. The third interlayer insulating layer 57 may be formed of a silicon oxide layer (e.g., a high density plasma oxide layer, a BPSG layer, a PE-TEOS or the like). The second hard mask layer 59 may function as an etch stop (or stopper) layer during subsequent contact etching processes. The second hard mask layer 59 may have an etch selectivity with respect to an interlayer insulating layer to be formed thereon. The second hard mask layer 59 may be formed of silicon nitride (SiN) or silicon oxide nitride. The second hard mask layer 59 may have a thickness of 200-1000 Å.

Contact holes 61, which expose the source and drain regions 33 and 34, and the first and second metal silicide layers 41 and 56 on the gate electrode, may be formed by any photolithography process well-known in the art. A tungsten layer (not shown) may be formed in the contact holes 61. A barrier metal layer (not shown) may be interposed between the tungsten layer and the contact holes 61. The tungsten layer may be planarized by performing an etching process until the second hard mask pattern 59 is exposed in order to form contact plugs 63a, 63b, 63c, 63d, 63e and 63f. The etching process may include a CMP process having an etch selectivity with respect to the tungsten layer and the second hard mask layer 59.

Referring to FIG. 28, a conductive layer may be deposited (or formed) and patterned to form landing pads 65a, 65b, 65c and 65d connected to the contact plugs 63a, 63d, 63e, 63f. The landing pads 65a, 65b and/or 65d may function as drain pads. The drain pads may be connected to a bit line (not shown).

A fourth interlayer insulating layer 67 and a third hard mask layer 69 may be deposited (or formed). The fourth interlayer insulating layer 67 may be an insulating layer having a thickness sufficient to cover understructures when planarized. The fourth interlayer insulating layer 67 may be formed of silicon oxide layer (e.g., a high density plasma oxide layer, a BPSG layer, a PE-TEOS layer or the like). The third hard mask layer 69 may function as an etch stop (or stopper) layer in a subsequent contact etching process. The third hard mask layer 69 may have an etch selectivity with respect to an interlayer insulating layer to be formed thereon. The third hard mask layer 59 may be formed of silicon nitride (SiN) or silicon oxide nitride (SiON). The third hard mask layer 59 may have a thickness of 200-1000 Å.

A through hole 70, sequentially penetrating the third hard mask layer 69 and the fourth interlayer insulating layer 67, may be formed. The through hole 70 may be filled with a conductive material to form a storage node plug 71 connected to the contact plug 63c on the source region 33.

A fifth interlayer insulating layer 73 may be formed on the third hard mask layer 59. The fifth interlayer insulating layer 73 may be an insulating layer having a thickness sufficient to cover understructures when planarized. The fifth interlayer insulating layer 73 may be a silicon oxide layer (e.g., a high density plasma oxide layer, a BPSG layer, a PE-TEOS layer or the like).

An aperture 74, which exposes the storage node plug 71, may be formed in the fifth interlayer insulating layer 73. A storage electrode 81 may be formed on the aperture 74. The storage electrode 81 may be connected to the storage node plug 71. A dielectric layer 82 and an upper electrode 83 may be formed sequentially on the storage electrode 81. The dielectric layer 82 and the upper electrode 83 may be patterned to form a capacitor 80 of a DRAM device. Although example embodiments illustrate the formation of one DRAM device in an active region, example embodiments are not limited thereto (e.g., a pair of DRAM devices may be formed in one active region).

In other example embodiments, a mask pattern of a gate electrode may be formed by a process illustrated in FIG. 10B.

Referring to FIG. 10B, a fourth hard mask layer (not shown) may be formed on a dummy gate layer 19 and a first hard mask pattern 28a. The fourth hard mask layer may have an etch selectivity with respect to the first hard mask pattern 28a and the gate conductive layer 25. A photoresist layer (not shown) may be formed on the fourth hard mask layer. A photoresist pattern 30 may be formed by performing a photolithography process, which is used to form a gate electrode, on the photoresist layer. A fourth hard mask pattern 28b may be formed from the fourth hard mask layer using the photoresist pattern 30 as an etching mask.

The dummy gate layer 19 and the gate conductive layer 25 may be dry etched using the fourth hard mask pattern 28b as an etching mask. The photoresist pattern 30 and the fourth hard mask pattern 28b may be removed to form a dummy pattern 20 and a second gate electrode 26, as illustrated in FIG. 11.

In accordance with other example embodiment, another method of forming a recess region will now be described.

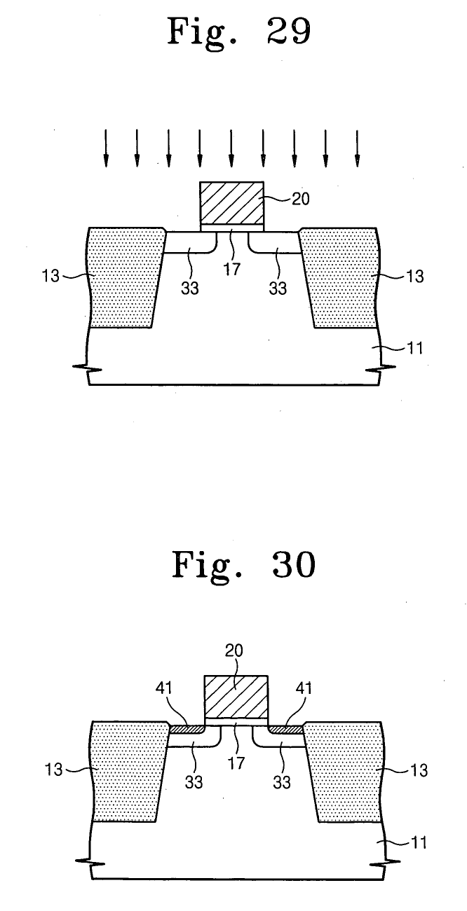

FIGS. 29 to 34 are diagrams illustrating cross-sectional views of a first region (A) in a method of fabricating a semiconductor device according to example embodiments.

Referring to FIG. 29, a photoresist pattern (not shown) may be formed on a semiconductor substrate 11 having a dummy pattern 20 in a first region (A) (as illustrated in FIG. 11). Impurity ions may be implanted using the photoresist pattern as a mask to form impurity regions. If the semiconductor device is a NMOS transistor, the impurity region may be formed by implanting phosphorous or arsenic with an energy of 10-30 keV and a dose of approximately 5×10¹⁴-1×10¹⁵ atoms/cm². If the semiconductor device is a PMOS transistor, boron ions may be implanted with an energy of 10-30 keV and a dose of approximately 5×10¹⁴-1×10¹⁵ atoms/cm².

The photoresist pattern (not shown) for impurity ion implantation may be removed. A heat treatment process may be performed to activate the impurity ions implanted in the semiconductor substrate 11. Source and drain regions 33 may be formed at sides of the dummy pattern 20. The heat treatment process may be performed at a high temperature of about 1000° C.

Referring to FIG. 30, a first metal layer (not shown) may be deposited (or formed) and heat-treated to form a metal silicide layer 41 on the source and drain regions 33 at sides of the dummy pattern 20. The first metal layer may be formed of any metal that maintains stable properties during a thermal oxidation process performed at a temperature of 850° C. lower in order to form a gate insulating layer. The metal may be cobalt or titanium.

If the first metal layer is a cobalt layer, then a first heat treatment may be performed on the cobalt layer in a temperature range of 450-540° C. Unreacted cobalt may be removed by a wet etching solution. A second heat treatment may be performed thereon in a temperature range of 700-850° C. in order that a cobalt silicide layer is formed.

If the first metal layer is a titanium layer, then a first heat treatment may be performed on the titanium layer at a temperature of about 650° C. Unreacted titanium may be removed using a wet etching solution. A second heat treatment may be performed thereon at a temperature of about 800° C. in order that a titanium silicide layer is formed. As a result, the metal silicide layer 41 may be a cobalt silicide layer or a titanium silicide layer. The metal silicide layer 41, which is formed on the source and drain region 33, may be self-aligned with the dummy pattern 20.

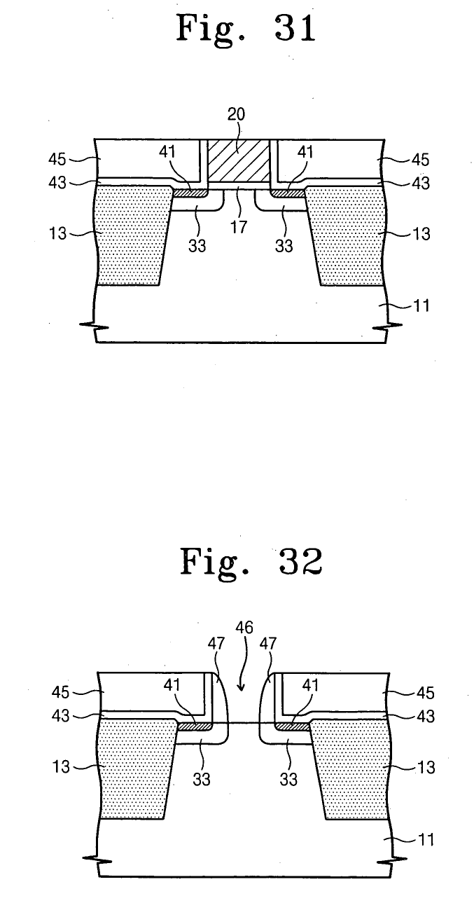

Referring to FIG. 31, a first interlayer insulating layer 43 and a second interlayer insulating layer 45 may be sequentially deposited (or formed). The first interlayer insulating layer 43 may function as an etch stop (or stopper) layer during subsequent etching processes. The first interlayer insulating layer 43 may be a silicon nitride layer (SiN) or a silicon oxide nitride layer (SiON). The first interlayer insulating layer 43 may have a thickness of 200-1000 Å. The second interlayer insulating layer 45 may be an insulating layer having a thickness sufficient to cover understructures when planarized. The second interlayer insulating layer 45 may have an high etch selectivity with respect to the dummy pattern 20. The second interlayer insulating layer 45 may be formed of a silicide oxide layer (e.g., a high density plasma oxide layer, a BPSG layer, a PE-TEOS layer or the like).

The second interlayer insulating layer 45 and the first interlayer insulating layer 43 may be planarized by etching until the dummy pattern 20 is exposed. The etching may include performed a CMP process having etch selectivity with respect to the first and second interlayer insulating layers 43 and 45 compared to the dummy pattern 20.

Referring to FIG. 32, the dummy pattern 20 may be removed by an etching process in order to form an aperture 46 exposing the semiconductor substrate 11. An insulating layer (not shown) may be formed to fill a portion of the aperture 46. A dry-etching process may be performed on the insulating layer to form spacers 47 on sidewalls of the first interlayer insulating layer 43, leaving a portion of the semiconductor substrate 11 between the aperture 46 exposed. The width of the spacers 47 may be sufficient to cover the metal silicide layer 41 in order to prevent (or reduce) exposure of the metal silicide layer 41 in subsequent etching processes.

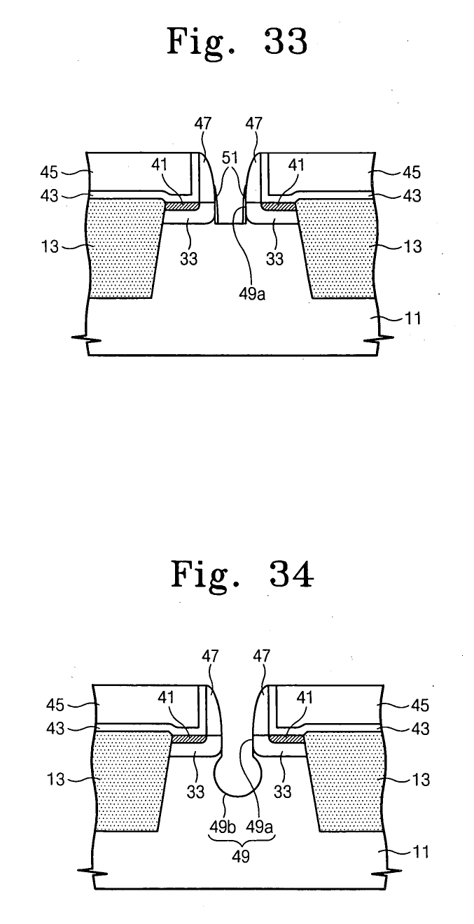

Referring to FIG. 33, the exposed semiconductor substrate 11 may be anisotropically etched using the first interlayer insulating layer 43, the second interlayer insulating layers 45 and the spacers 47 as an etching mask. The anisotropic etching process may include a dry etching process, forming a first recess region 49a. The first recess region 49a may be formed to a depth of 400-1000 Å. The first recess region 49a may be formed deeper than a bottom (or lower) surface of the metal silicide layer 41.

An etching barrier layer (not shown) may be conformably formed on the semiconductor substrate 11 having a thickness of 50-300 Å. The anisotropic etching process may be performed on the etching barrier layer in order to form etching barrier spacers 51 covering sidewalls of the first recess region 49a while exposing the bottom (or lower) surface of the recess region 49. The etching barrier layer may be formed of a material having an etch selectivity with respect to the semiconductor substrate 11. The etching barrier layer may be a silicon nitride layer, a silicon oxide nitride layer or a silicon oxide layer.

Referring to FIG. 34, an isotropic etching process may be performed on the semiconductor substrate 11 having the etching barrier spacers 51. A second recess region 49b having a circular profile may be formed under the first recess region 49a, forming a recess region 49. The etching depth may be 300-1000 Å. The isotropic etching process may include a wet etching process. The etching barrier spacers 51 may prevent (or reduce) etching of the sidewalls of the first recess region 49a during the isotropic etching process.

The recess region 49 includes the first recess region 49a and the second recess region 49b. The first recess region 49a may be formed in the semiconductor substrate 11. The second recess region 49b may be connected with the first recess region 49a thereunder.

The following processes may be performed in a similar manner as the processes illustrated in FIGS. 25 to 28 according to example embodiments.

As described in example embodiments, a junction region even for a highly-integrated semiconductor device may have a greater depth due to the use of a recessed channel. As such, a silicide layer may be formed without any (or minimal) leakage current. Also, contact resistance in the highly-integrated semiconductor device may be reduced.

The source, drain and recess regions may be self-aligned with the dummy pattern because source regions, drain regions and recess region are formed using the dummy pattern. As such, deterioration of a transistor, which occurs due to misalignment in a recess channel transistor in the conventional art, may be more effectively prevented (or reduced).

Also, undesirable movement of a void (or deformation of a transistor), which is observed in the recessed channel transistor of the related art, may be prevented (or reduced) because the recess region and the gate electrode may be formed after the source regions, drain regions and silicide layer are formed.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of fabricating a semiconductor device, the method comprising:
forming a dummy pattern on a semiconductor substrate;
forming source and drain regions at sides of the dummy pattern on the semiconductor substrate;
forming a first metal silicide layer on the source and drain regions;
forming a recess region in the semiconductor substrate under the dummy pattern; and
forming a first gate insulating layer and a first gate electrode in the recess region.

2. The method of claim 1, wherein forming the dummy pattern includes forming a material layer on the semiconductor substrate, wherein the material layer has an etch selectivity with respect to a silicon oxide layer; and patterning the material layer.

3. The method of claim 1, wherein forming the first metal silicide layer includes forming first spacers on sidewalls of the dummy pattern; forming a first metal layer on an entire surface of the semiconductor substrate having the dummy pattern and the first spacers; and performing a heat treatment to silicidate the first metal layer.

4. The method of claim 3, further comprising:
forming an etch stop layer on the semiconductor substrate having the first metal silicide layer;
forming an interlayer insulating layer on the etch stop layer;
planarizing the interlayer insulating layer to expose the etch stop layer;
selectively etching the etch stop layer to expose an upper surface of the dummy pattern; and
removing the dummy pattern to expose a surface of the semiconductor substrate, before forming the recess region.

5. The method of claim 4, wherein the first metal silicide layer is a cobalt silicide layer or a titanium silicide layer.

6. The method of claim 5, wherein forming the recess region includes etching the exposed surface of the semiconductor substrate using the first spacers and the interlayer insulating layer as an etching mask.

7. The method of claim 6, further comprising forming second spacers on sidewalls of the recess region; and isotropically etching the semiconductor substrate exposed by a lower portion of the recess region.

8. The method of claim 7, wherein a bottom surface of the recess region is lower than a bottom surface of the first metal silicide layer.

9. The method of claim 7, wherein forming the first gate electrode includes:
forming a gate conductive layer in the recess region;
planarizing the gate conductive layer to expose the interlayer insulating layer;
forming a second metal layer on an entire surface of the semiconductor substrate having the exposed interlayer insulating layer; and
performing a heat treatment to form a second metal silicide layer on the gate conductive layer.

10. The method of claim 9, wherein the second metal silicide layer is a nickel silicide layer.

11. The method of claim 1, wherein the gate insulating layer is formed at a temperature of 850° C. or lower.

12. The method of claim 1, further comprising:
forming an interlayer insulating layer on the semiconductor substrate and the dummy pattern, wherein the interlayer insulating layer has an etch selectivity with respect to the dummy pattern;
planarizing the interlayer insulating layer to expose the dummy pattern;
removing the dummy pattern; and
forming first spacers facing each other on sidewalls of the interlayer insulating layer, wherein the semiconductor substrate between the first spacers is exposed.

13. The method of claim 1, further comprising:
preparing the semiconductor substrate including a first region and a second region before forming the dummy pattern, wherein the dummy pattern is formed on the first region for the first gate electrode;
forming a second gate insulating layer and a second gate electrode on the second region, wherein said source and drain regions are formed at sides of the second gate electrode; and
forming first spacers at the sides of the dummy pattern and at the sides of the second gate electrode,
wherein the first metal silicide layer is formed on an upper surface of the second gate electrode.

14. The method of claim 13, wherein the first metal silicide layer is a cobalt silicide layer or a titanium silicide layer.

15. The method of claim 13, wherein forming the dummy pattern includes:
forming a material layer on the semiconductor substrate, wherein the material layer has an etch selectivity with respect to a silicon oxide layer; and
patterning the material layer.

16. The method of claim 15, further comprising:
forming an etch stop layer on the semiconductor substrate having the first metal silicide layer;
forming an interlayer insulating layer on the etch stop layer;
planarizing the interlayer insulating layer to expose the etch stop layer;
selectivity etching the etch stop layer exposed on the first region while a photoresist is formed on the second region and an upper surface of the dummy pattern is exposed; and
removing the dummy pattern to expose a surface of the semiconductor substrate of the first region, before forming the recess region.

17. The method of claim 16, wherein forming the recess region includes etching the exposed surface of the semiconductor substrate of the first region using the first spacers and the interlayer insulating layer as an etching mask.

18. The method of claim 17, further comprising forming second spacers on sidewalls of the recess region; and isotropically etching the semiconductor substrate exposed from a lower portion of the recess region.

19. The method of claim 18, wherein a bottom surface of the recess region is lower than a bottom surface of the first metal silicide layer.

20. The method of claim 18, wherein forming the first gate electrode includes:
forming a gate conductive layer in the recess region;
planarizing the gate conductive layer to expose the interlayer insulating layer;
forming a second metal layer on an entire surface of the semiconductor substrate having the exposed interlayer insulating layer; and
performing a heat treatment on the second metal layer to form a second metal silicide layer on the gate conductive layer.

21. The method of claim 20, wherein the second metal silicide layer is a nickel silicide layer.

22. A semiconductor device, comprising:
a first gate insulating layer and a first gate electrode in a recess region of a semiconductor substrate;
a first source region and a first drain region formed in the semiconductor substrate at sides of the first gate electrode; and
a first metal silicide layer on the first source region and the first drain region,
wherein the first gate electrode includes a second metal silicide layer formed thereon, and the first metal silicide layer and the second metal silicide layer are formed of different metals.

23. The semiconductor device of claim 22, further comprising:
a second gate insulating layer and a second gate electrode formed in another region of the semiconductor substrate;
a second source region and a second drain region formed in the semiconductor substrate at sides of the second gate electrode; and
the first metal silicide layer formed on the second source region and the second drain region, wherein the second gate electrode includes the first metal silicide layer formed thereon.

24. The semiconductor device of claim 22, wherein the first metal silicide layer maintains a stable state at a temperature of 850° C.

25. The semiconductor device of claim 24, wherein the first metal silicide layer is a cobalt silicide layer or a titanium silicide layer.

26. The semiconductor device of claim 22, wherein the second metal silicide layer is a nickel silicide layer.

27. The semiconductor device of claim 22, wherein a bottom surface of the recess region is lower than a bottom surface of the first metal silicide layer.

28. The semiconductor device of claim 22, wherein the recess region includes:
a first recess region formed in the semiconductor substrate; and
a second recess region in contact with the first recess region, wherein the second recess region has a circular profile and is formed under the first recess region.
